(19) United States
(12) Patent Application Publication
(10) Pub. No.: US 2026/0043883 A1
(43) Pub. Date: Feb. 12, 2026

(54) IMAGING PHANTOM

(71) Applicant: UAB RESEARCH FOUNDATION, Birmingham, AL (US)

(72) Inventor: Harrison Kim, Birmingham, AL (US)

(21) Appl. No.: 19/100,654

(22) PCT Filed: Aug. 3, 2023
(86) PCT No.: PCT/US2023/029409

§ 371 Date: Feb. 3, 2025

Related U.S. Application Data
(60) Provisional application No. 63/394,836, filed on Aug. 3, 2022.

(51) Int. Cl. G01R 33/58; G01R 33/563

(52) U.S. Cl. CPC G01R 33/58; G01R 33/563

(57) ABSTRACT

A disposable imaging phantom including a top housing having an inlet, and outlet, and first chamber in communication with the inlet and outlet and a bottom housing having a second chamber. The bottom housing connects to the top housing. The first 2024/030553 and second chamber are configured to receive a first fluid. The first chamber is configured to receive a second fluid through the inlet to displace the first fluid through the outlet. The imaging phantom also includes a membrane assembly configured to be positioned between portions of the top and bottom housings. The membrane assembly includes a semi-permeable membrane configured to permit diffusion of the second fluid from the first chamber into the second chamber.

### CROSS REFERENCE TO RELATED APPLICATIONS

This application is based upon and claims benefit of priority to U.S. Provisional Application No. 63/394,836, filed Aug. 3, 2022, which application is hereby incorporated by reference herein in its entirety.

### STATEMENT OF GOVERNMENT SUPPORT

This invention was made with government support under Grant UG3 CA232820 awarded by the National Institutes of Health. The government has certain rights in the invention.

### FIELD

Disclosed herein is a disposable imaging phantom. In exemplary aspects, the disclosed imaging phantom can be used to evaluate, analyze, and/or calibrate the performance of imaging devices, and/or to normalize data obtained by imaging devices.

### BACKGROUND

Imaging phantoms simulating characteristics of the human body may be used to evaluate, analyze and calibrate the performance of imaging devices. Further, imaging devices may be used concurrently with a subject to normalize data obtained by the imaging device. However, existing phantoms have long assembly times (0.5 hours or more) and brief shelf lives (a few days) due to leakage or internal bubbles.

Thus, there is a need for an imaging phantom that addresses one or more of the deficiencies of existing imaging phantoms. For example, there is a need for an imaging phantom that can be assembled quickly and can effectively seal liquid contained therein.

### SUMMARY

Described herein, in various aspects, is an imaging phantom. The imaging phantom may be a disposable imaging phantom. The imaging phantom may have a top housing and a bottom housing. The top housing may have an inlet, an outlet, and a first chamber. The first chamber may be in communication with the inlet and the outlet. The bottom housing may have a second chamber. The bottom housing may be configured to connect to the top housing. The first chamber and the second chamber may be configured to receive a first fluid. The first chamber may be configured to receive a second fluid through the inlet of the top housing to displace the first fluid through the outlet of the top housing. The imaging phantom may have a membrane assembly configured to be positioned between portions of the top housing and portions of the bottom housing. The membrane assembly may comprise a semi-permeable membrane that is configured to permit diffusion of the second fluid from the first chamber into the second chamber.

### DESCRIPTION OF THE DRAWINGS

FIG. 1 is a front isometric view of an exemplary imaging phantom as disclosed herein.

FIG. 2 is an exploded view of the exemplary imaging phantom of FIG. 1.

FIG. 3 is a top view of the exemplary imaging phantom of FIG. 1.

FIG. 4 is an isometric view of an exemplary inlet, outlet, and first chamber of the top housing of the exemplary imaging phantom of FIG. 1.

FIG. 5A is a top view of the exemplary inlet, outlet, and first chamber of the top housing of FIG. 4.

FIG. 5B is a side view of the exemplary inlet, outlet, and first chamber of the top housing of FIG. 5A.

FIG. 5C is a cross-sectional view of the exemplary inlet, outlet, and first chamber of the top housing of FIG. 4, taken at section line 5C-5C in FIG. 5A.

FIG. 6 is a graph showing an estimated change of gadoteridol concentration in an example first chamber using computed fluid dynamics.

FIG. 7 is a front isometric view of an exemplary first end portion of the exemplary imaging phantom of FIG. 1 connected to an exemplary coupling assembly.

FIG. 8A is a cross-sectional view of the exemplary first end portion of the exemplary imaging phantom of FIG. 1, taken at section line 8A-8A in FIG. 7.

FIG. 8B is an exploded view of the cross-section of FIG. 8A.

FIG. 9A is a top view of an exemplary second end portion of the exemplary imaging phantom of FIG. 1 and an exemplary seal engagement assembly.

FIG. 9B is a top view of the exemplary second end portion and exemplary seal engagement assembly of FIG. 9A with the exemplary seal engagement assembly engaged and connected to the exemplary second end portion.

FIG. 10A is a cross-sectional view showing an exemplary rod of the exemplary seal engagement being inserted into an exemplary outlet and expandable seal of the exemplary second end portion.

FIG. 10B is a cross-sectional view of the exemplary second end portion and exemplary seal engagement assembly of FIG. 9A, taken at section line 10B-10B in FIG. 9B.

FIG. 11 shows a process of assembling an exemplary imaging phantom.

FIG. 12 is a bottom view of the exemplary imaging phantom of FIG. 1.

FIG. 13 is an isometric view of exemplary channels within the exemplary imaging phantom configured to receive a bonding fluid.

FIG. 14 is an isometric view of an exemplary disposable point-of-care portable perfusion phantom.

FIG. 15 is an isometric view of an exemplary phantom cassette

FIGS. 16A and 16B are isometric views of the exemplary phantom cassette of FIG. 15. As shown, the exemplary phantom cassette is able to house up to three phantoms. Sorbothane pads on the bottom of the cassette dampen transmitted vibrations. The cable indicated by white arrows allows the location of the phantoms to be adjusted by up to 15 cm longitudinally.

FIG. 17 is an isometric view of an exemplary tabletop insert. As shown, exemplary imaging phantoms are located under the exemplary tabletop insert.

FIG. 18 is an isometric view of a human subject lying on an exemplary tabletop insert. The exemplary insert can support up to 136 kg of body weight, when the human subject sits on it. A cable controller (marked with the arrow) may be located at the end of the exemplary insert to adjust the phantom location.

FIG. 19 is an isometric view of an exemplary tabletop insert stacked for convenient carrying and storage.

FIG. 20 is a graph of a reference contrast enhancement curve (CEC). The samples were collected from the phantom every minute for 10 min after initiating gadoteridol infusion (100 mM, 0.24 ml/s, 4 ml), and the contrast agent concentration (CAC) was measured using the LC-MS method. This process was repeated for 10 times, and mean and standard deviation are shown.

FIG. 21 show contrast agent concentration (CAC) maps of five imaging phantoms at 2, 3, and 5 min after imaging initiation.

FIG. 22 is a graph of contrast enhancement curves (CECs) of the five imaging phantoms together with the mean value. The intraclass correlation coefficient (ICC) of five CECs was 0.997.

FIGS. 23A and 23B show K^{trans} maps of a healthy volunteer obtained from Scanner 1 (first column), Scanner 2 (second column), and Scanner 3 (third column) when the Tofts model (TM), extended Tofts model (ETM), and shutter speed model (SSM) were employed with a population-based arterial input function before and after phantom-based error correction. All three scans were completed within a week. The imaging phantom reduced the interscanner variability.

FIG. 24 shows Table 1: PK parameters of each tissue averaged over three measurements of five human subjects before and after phantom-based error correction.

FIG. 25 shows Table 2: The intraclass correlation coefficient (ICC) of each PK parameter of four organs (liver, spleen, muscle, and pancreas) of five healthy volunteers over three MRI scanners before and after phantom-based error correction.

FIG. 26 shows Table 3: The within-subject coefficient of variation (wCV) of each PK parameter in each tissue of five healthy volunteers over three MRI scanners before and after phantom-based error correction.

### DETAILED DESCRIPTION

The present invention now will be described more fully hereinafter with reference to the accompanying drawings, in which some, but not all embodiments of the invention are shown. Indeed, this invention may be embodied in many different forms and should not be construed as limited to the embodiments set forth herein; rather, these embodiments are provided so that this disclosure will satisfy applicable legal requirements. Like numbers refer to like elements throughout. It is to be understood that this invention is not limited to the particular methodology and protocols described, as such may vary. It is also to be understood that the terminology used herein is for the purpose of describing particular embodiments only, and is not intended to limit the scope of the present invention.

Many modifications and other embodiments of the invention set forth herein will come to mind to one skilled in the art to which the invention pertains having the benefit of the teachings presented in the foregoing description and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

As used herein the singular forms “a”, “an”, and “the” can optionally include plural referents unless the context clearly dictates otherwise. For example, use of the term “a chamber” can refer to one or more of such chambers unless the context indicates otherwise. Thus, disclosure of an element in singular form can provide support for embodiments including only a single element as well as for embodiments including a plurality of the same element.

All technical and scientific terms used herein have the same meaning as commonly understood to one of ordinary skill in the art to which this invention belongs unless clearly indicated otherwise.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

The word “or” as used herein means any one member of a particular list and, except where otherwise indicated, can also include any combination of members of that list. However, it should be understood that disclosure of individual elements within a list that includes the word “or” provides supports for embodiments in which only a single one of the listed elements is included, as well as for alternative embodiments in which more than one of the listed elements is included.

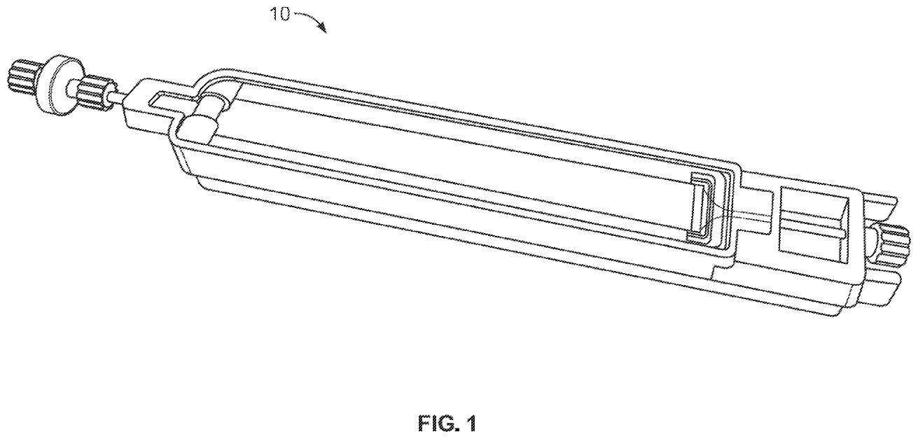

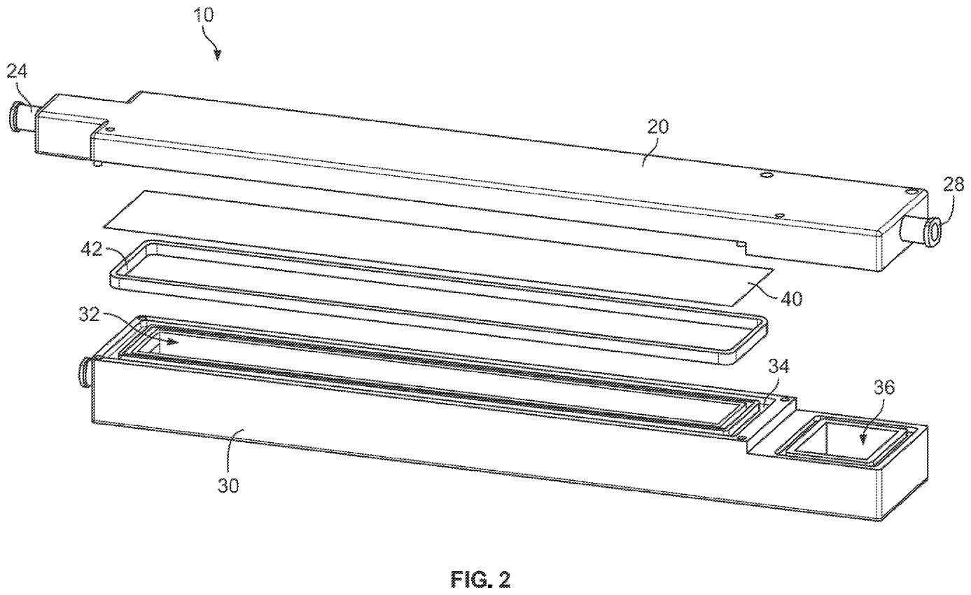

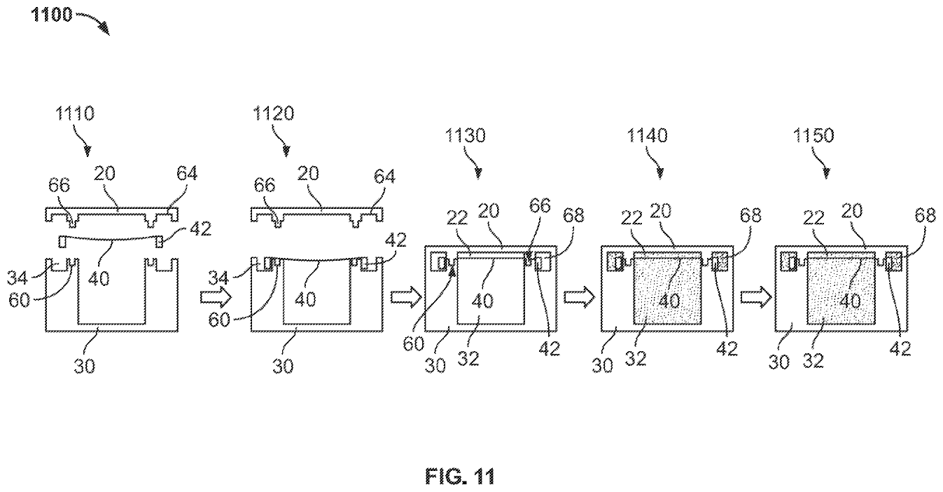

Disclosed herein with reference to FIG. 1 is an imaging phantom 10. The imaging phantom 10 may be disposable. The imaging phantom 10 may be assembled quickly and efficiently. Further, the imaging phantom 10 may have a shelf life longer than conventional imaging phantoms. As shown in FIG. 2, the imaging phantom 10 may include a top housing 20 and a bottom housing 30. The top housing 20 and the bottom housing 30 are configured to connect together. The imaging phantom 10 may also include a membrane assembly comprising a semi-permeable membrane 40. The membrane assembly may include a frame 42. The membrane assembly including the semi-permeable membrane 40 and frame 42 may be positioned between the top housing 20 and the bottom housing 30. In one aspect, the frame 42 may be rigid. The frame 42 may be configured to be positioned within a channel 34 of the bottom housing 30. In one aspect, the top housing 20 may also have a corresponding channel 64 configured to receive the frame 42 (see FIG. 11). Alternatively, only the top housing 20 may include a channel 64 configured to receive the frame 42. The channel 64 in the top housing 20 and the channel 34 in the bottom housing 30 may be configured to align when the top housing 20 and bottom housing 30 are connected forming a peripheral channel 68 configured to receive a bonding fluid to connect and/or secure the top housing 20, the bottom housing 30, and the frame 42 (see FIG. 11).

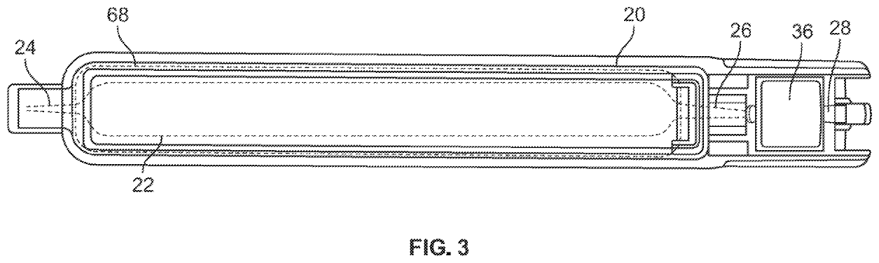

The top housing 20 may include a first chamber 22 (shown in FIG. 3-5C). The first chamber 22 may be configured to receive a fluid through an inlet 24. The bottom housing 30 may include a second chamber 32. Fluid in the first chamber 22 may diffuse through the semi-permeable membrane 40 into the second chamber 32. In one aspect, after the top housing 20, the bottom housing 30, and the semi-permeable membrane 40 are assembled, a first fluid may be injected through the inlet 24 to fill or substantially fill the first chamber 22 and the second chamber 32. In one exemplary aspect, the first fluid may be a non-contrast solution. In further exemplary aspects, the first fluid may be degassed and deionized water. Excess fluid may spill out from an outlet 26 in the top housing 20 (shown in FIGS. 3-5C) and into a waste chamber 36 in the bottom housing 30. A bonding agent may be injected into the channel 34 to secure the top housing 20, the bottom housing 30, and the semi-permeable membrane 40 together. In one aspect, the bonding agent may be an epoxy. The top housing 20 may include an opening 28 configured to receive a seal engagement assembly configured to seal the imaging phantom 10 after assembly and prior to use. The assembled imaging phantom 10 may have shelf stability for at least six months. During its shelf life, the first fluid may be sealed within the imaging phantom 10 without leakage or forming internal bubbles. It is important to eliminate bubbles within the imaging phantom 10 because internal bubbles may induce errors in the phantom value, leading to inaccuracies in the phantom-based error correction. For example, if 5% of the second chamber 32 contains bubbles, the phantom value may be 5% overestimated.

In use, a second fluid may be infused into the imaging phantom 10 through the inlet 24. The second fluid may displace the first fluid in the first chamber 22. The displaced first fluid may exit the first chamber 22 through the outlet 26 and may be transferred to the waste chamber 36. The second fluid may diffuse through the semi-permeable membrane 40 into the second chamber 32. In one aspect the second fluid may be a contrast agent. In one example, during an imaging procedure, such as an MRI scan, a contrast agent may be injected into the first chamber 22 through the inlet 24, may displace the water in the first chamber 22 forcing the water through the outlet 26 and into the waste chamber 36, and may diffuse through the semi-permeable membrane 40 to the second chamber 32. The second fluid may diffuse into the first fluid in the second chamber 32 at a desired rate. In exemplary aspects, the desired rate can be a substantially constant rate during an initial perfusion period, which can correspond to a time of less than or equal to 10 minutes after injection of contrast agent, less than or equal to 9 minutes after injection of contrast agent, less than or equal to 8 minutes after injection of contrast agent, less than or equal to 7 minutes after injection of contrast agent, less than or equal to 6 minutes after injection of contrast agent, less than or equal to 5 minutes after injection of contrast agent, less than or equal to 4 minutes after injection of contrast agent, less than or equal to 3 minutes after injection of contrast agent, less than or equal to 2 minutes after injection of contrast agent, or less than or equal to 1 minute after injection of contrast agent. In exemplary aspects, it is contemplated that a substantially constant rate can be a constant rate. In further exemplary aspects, it is contemplated that a substantially constant rate can deviate (upwardly or downwardly) from the desired rate during a portion of the contrast agent flow by up to 25 percent, up to 20 percent, up to 15 percent, up to 10 percent, or up to 5 percent. The rate of contrast change in the second chamber 32 may be used as a reference to detect and/or correct imaging device errors. For example the rate of contrast change may be used to increase or decrease the contrast agent concentration in all tissues. The contrast rate may be used to correct the pharmacokinetic parameters of the tissues accordingly.

In exemplary aspects, and with reference to FIGS. 3-5C, the top housing 20, including the first chamber 22, the inlet 24, and the outlet 26, may be designed to optimize fluid displacement. Fluid displacement, including the infusion speed and the amount of contrast agent, should be optimized to ensure that all of the first fluid is effectively displaced with the second fluid at an efficient speed. If the infusion rate is too fast, only the first fluid towards the center of the first chamber 22 may be displace. If the infusion rate is too slow, the second fluid may be diluted with the first fluid, and further, the diffusion of the second fluid into the second chamber 32 may be delayed, leading to extended image acquisition time. The top housing 20, including the first chamber 22, the inlet 24, and the outlet 26, may be designed to optimize the efficiency at which the second fluid, such as a contrast agent, displaces the first fluid, such as a non-contrast solution. In one aspect, the geometric configuration of the first chamber 22, the inlet 24, and the outlet 26 may be optimized to facilitate the displacement of the first fluid. In further exemplary aspects, the inlet 24 diameter D_{I}, the outlet 26 diameter D_{O}, the inlet 24 length L_{I}, the outlet 26 length L_{O}, and/or the cross-sectional shape of the first chamber 22 may be optimized to facilitate the displacement of the first fluid.

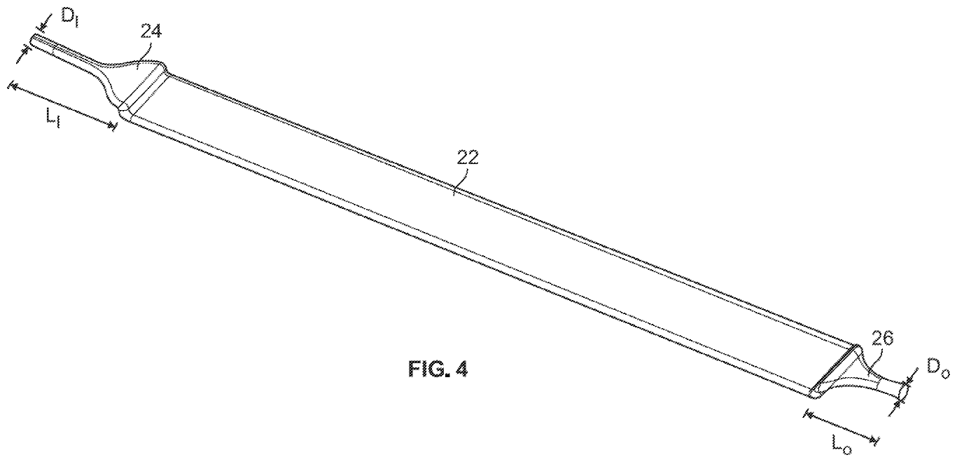

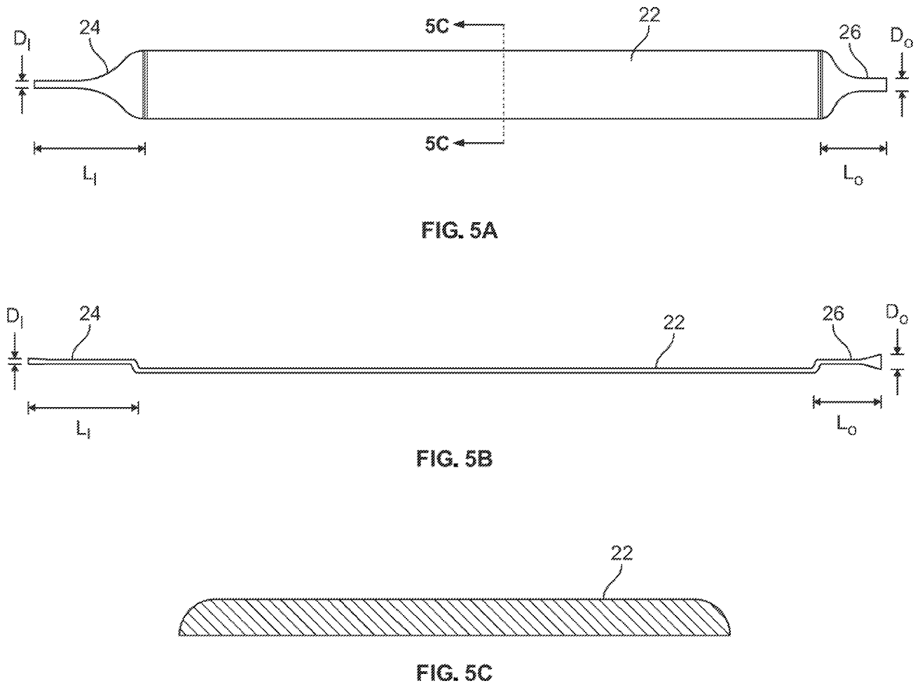

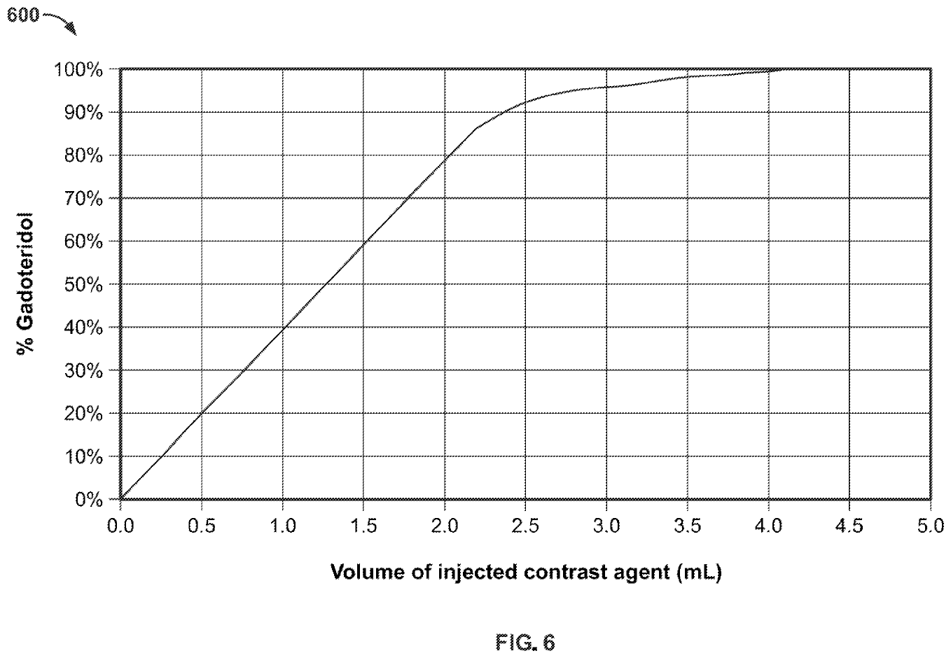

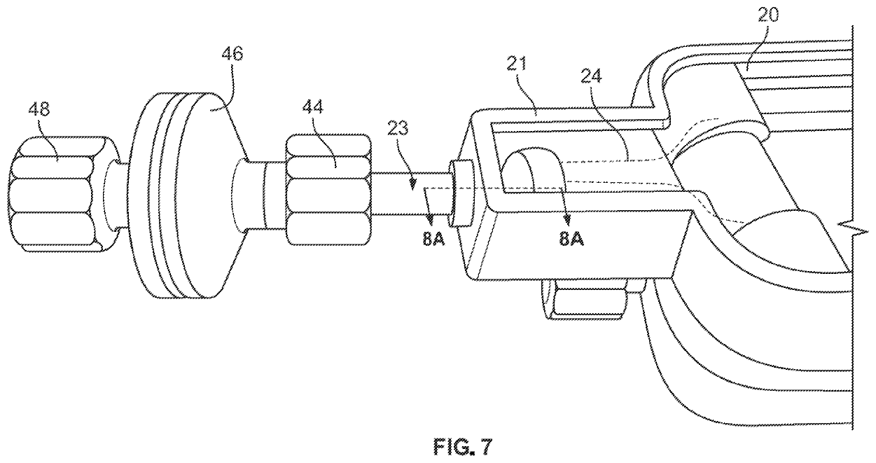

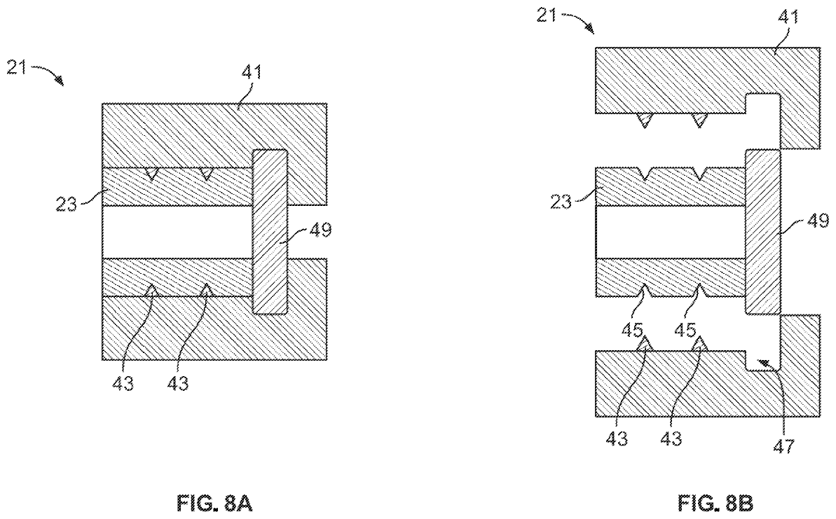

With reference to FIGS. 4-5B, the diameter D_{I} of the inlet 24 corresponds to an inner diameter of an inlet tube 23 (shown in FIGS. 7-8B). The inlet tube 23 may be configured to discharge fluid into the inlet 24. In one aspect, the tube 23 may inject the second fluid or contrast agent into the inlet 24. The inlet 24 may have a length L_{I} configured to facilitate the displacement of the first fluid from the inlet 24 into the first chamber 22. The pressure of the infusion may be high towards the center and low towards the edges of the inlet 24. Therefore, if the inlet 24 length L_{I} is too short, the first fluid towards the edges of the inlet 24 may not be effectively pushed out. The remaining first fluid in the inlet 24 may dilute the second fluid concentration, which may lead to quantification errors. However, if the inlet 24 length L_{I} is too long, the infusion time and the amount of the second fluid may be increased unnecessarily.

In exemplary aspects, the outlet 26 may have a diameter D_{O} that is larger than the diameter D_{I} of the inlet 24. In one aspect, the outlet 26 may have a length Lo that is shorter than the length L_{I} of the inlet 24. An outlet 26 diameter D_{O} larger than the inlet 24 diameter D_{I} and/or an outlet 26 length Lo shorter than the inlet 24 length L_{I} may reduce pressure from the injected second fluid within the first chamber 22. Reducing the pressure within the first chamber 22 may reduce pressure on the semi-permeable membrane 40. Pressure on the semi-permeable membrane 40 may cause the semi-permeable membrane 40 to sag or may even cause damage to the semi-permeable membrane 40. These features, which reduce the pressure on the semi-permeable membrane 40, may thereby prevent the semi-permeable membrane 40 from sagging or from being damaged.

With reference to FIGS. 4 and 5B, the inlet 24 and the outlet 26 may be offset from the first chamber 22 along a vertical axis. The inlet 24 and outlet 26 may be configured to be positioned closer to an upper surface of the top housing 20 to provide space below to accommodate portions of the channel 64 (shown in FIG. 11) positioned near the circumference of the top housing 20. The offset of the inlet 24 and the outlet 26 thereby enables the formation of the peripheral channel 68 used to connect the top housing 20, the bottom housing 30, and the frame 42 with bonding fluid.

With reference to FIG. 5C, the cross-section of the first chamber 22 may have a design to improve the efficiency of the displacement of the first fluid by the second fluid. In exemplary aspects, the inlet 24, the outlet 26, and/or the first chamber 22 may have rounded edges to optimize the displacement of the first fluid by the second fluid. Rounded edges may result in a more uniform pressure of the infusion allowing the first fluid to be more effectively pushed out by the second fluid, whereas squared edges may result in low pressure of infusion at the corners of the chamber 22 which may result in the first fluid to be ineffectively pushed out by the second fluid.

In an example aspect and with reference to FIG. 6, a computed fluid dynamics (CFD) simulation was performed on an example imaging phantom 10 having the optimizing fluid displacement features described herein. In this example, the first fluid was water and the second fluid was a gadoteridol concentration contrast agent. The graph 600 shows an estimated change of gadoteridol concentration in the first chamber 22 using CFD assuming that the gadoteridol was infused via the inlet 24 at a constant rate (0.24 ml/s). After infusing 4 ml of gadoteridol, it is estimated that 99.2% of the water in the first chamber 22 is displaced by the gadoteridol.

In exemplary aspects, and as shown in FIG. 7, it is contemplated that the top housing 20 of the imaging phantom 10 may comprise a first end portion 21. The first end portion 21 may comprise the inlet 24 (shown in phantom). The inlet 24 may be configured to connect to a coupling assembly configured to deliver fluid to the inlet 24. The inlet 24 may be connected to a tube 23. The tube 23 may transfer the first and/or the second fluid into the inlet 24. The tube 23 may be flexible thereby creating a connection that may withstand movement and absorb vibration which may negatively affect the image captured by the imaging device by causing artifacts in the image. The tube 23 may be connected to a valve 46. Optionally, the tube 23 may be connected to the valve 46 with a Luer lock fitting 44 configured for complementary engagement. In one aspect, the Luer lock fitting 44 is configured to connect a female end of the valve 46 with the tube 23. Alternatively, the valve 46 may be directly connected to the tube 23 with a barbed outlet. In one aspect, the valve 46 may be a one-way check valve allowing the fluid to flow in only one direction. In one aspect, the valve 46 may be a disc valve. The valve 46 may be configured to capture bubbles. For example, the valve 46 may be configured to trap any bubbles that may form between the second fluid and the first fluid during connection in an upper portion of the disc thereby preventing the bubbles from entering the imaging phantom 10. The valve 46 may be connected to a cap 48. In this example, the cap 48 is a Luer lock cap. The cap 48 may be removed and the valve 46 may be connected to another tube having a male Luer lock adaptor for infusion of the second fluid.

With reference to FIGS. 8A and 8B, the first end portion 21 of the top housing 20 may comprise a connector 41 having an inner surface that defines a receiving space configured to receive a portion of the coupling assembly. The connector 41 may be configured to encompass the tube 23 connecting the tube 23 to the imaging phantom 10. In one aspect, the connector 41 is formed by the top housing 20. The connector 41 may comprise at least one projection 43 extending inwardly from the inner surface of the connector 41. The at least one projection 43 configured to engage the tube 23. In one aspect, each projection 43 may be a ring connected to the inner surface of the connector 41. The tube 23 may comprise at least one corresponding groove 45 defined in the outer surface of the tube 23 configured to receive a projection 43. Each projection 43 may penetrate a groove 45 to secure the tube 23 and prevent the tube 23 from slipping out of the connector 41. The connector 41 may also comprise a notch 47 configured to receive a seal 49. The seal 49 may prevent fluid leakage at the inlet 24. In this example, the seal 49 is an O-ring.

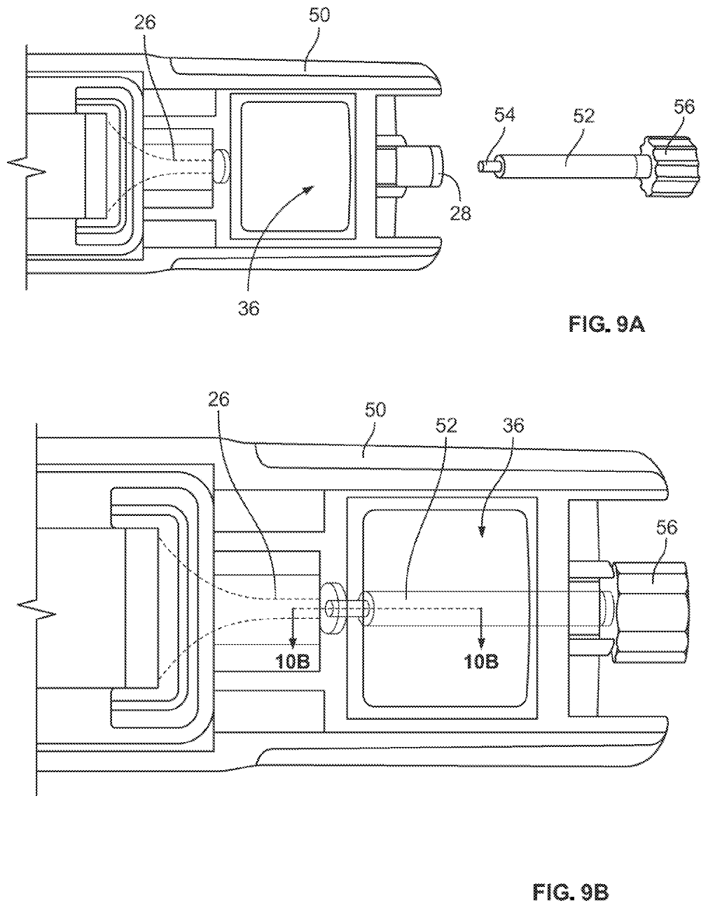

In exemplary aspects, and as shown in FIGS. 9A and 9B, it is contemplated that the top housing 20 of the imaging phantom 10 may comprise a second end portion 50. The second end portion 50 may comprise the outlet 26 and the opening 28. The second end portion 50 may be configured to seal the imaging phantom 10 filled or substantially filled with the first fluid for storage and/or transportation prior to being used. In one aspect, the imaging phantom 10 is sealed by inserting a rod 52 through the opening 28 and into the outlet 26. The rod 52 may comprise a tip 54 configured to insert into the outlet 26 and a cap 56 configured to secure the rod to the opening 28. The cap 56 may be unscrewed from the opening 28 and the rod 52 pulled out from the outlet 26 and opening 28 before the image phantom 10 is used.

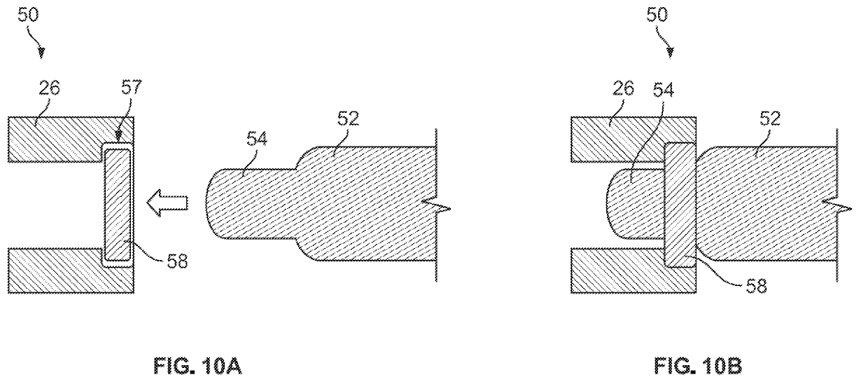

With reference to FIGS. 10A and 10B, a first end of the rod 52 may have a variable outer diameter. For example, the outer diameter of the end of the rod 52 may decrease towards the tip 54 of the rod 52. In exemplary aspects, and as shown in FIGS. 10A and 10B, the outlet 26 may comprise an opening 57 configured to receive a seal 58. The rod 52 may insert into the outlet 26 through the central bore of the seal 58 in the opening 57. As shown in FIG. 10B, the variable outer diameter of the rod 52 may radially expand the seal 58 within the opening 57 as the tip 54 is inserted thereby creating a tight seal and preventing fluid leakage at the outlet 26. In one aspect, the seal 58 may be an O-ring.

FIG. 11 shows a process 1100 that may be used to ensure the semi-permeable membrane 40 remains taut within the imaging phantom 10. When the semi-permeable membrane 40 is saturated, the semi-permeable membrane 40 may sag and/or wrinkle. Sagging and/or wrinkling of the semi-permeable membrane 40 may negatively affect the rate at which the second fluid diffuses through the semi-permeable membrane 40 invalidating any data obtained from the imaging phantom 10. At 1110, the semi-permeable membrane 40 and frame 42 may be soaked in a fluid, such as water, until saturated. In one example, the semi-permeable membrane 40 and frame 42 may be soaked for 30 minutes or more. Once saturated, the semi-permeable membrane 40 may sag. At 1120, the frame 42 may be placed in the channel 34 in the bottom housing 30. The slack semi-permeable membrane 40 may span the second chamber 32. The interior edge or side of the channel 34 may include a recess 60. The corresponding channel 64 in the top housing 20 may include an interior edge or side including a protrusion 66 which corresponds with the recess 60. In another aspect, the interior edge or side of the channel 34 in the bottom housing 30 may include the protrusion 66, and the interior edge or side of the channel 64 in the top housing 20 may include the recess 60. At 1130, the top housing 20 and the bottom housing 30 may be connected. The channel 34 in the bottom housing 30 and the channel 64 in the top housing 20 may align and form the peripheral channel 68. The frame 42 may be contained within the through channel 68. The protrusion 66 may insert into the recess 60 with the semi-permeable membrane 40 clamped between pulling the semi-permeable membrane 40 taut. The semi-permeable membrane 40 divides the first chamber 22 and the second chamber 32. At 1140, the first chamber 22 and the second chamber 32 may be filled or substantially filled with the first fluid. In this example, the first chamber 22 and the second chamber 32 may be filled with water. At 1150, the through channel 68 may be filled with the bonding fluid, such as epoxy, to secure the frame 42 within the peripheral channel 68 and to fix the semi-permeable membrane 40 in the taut position.

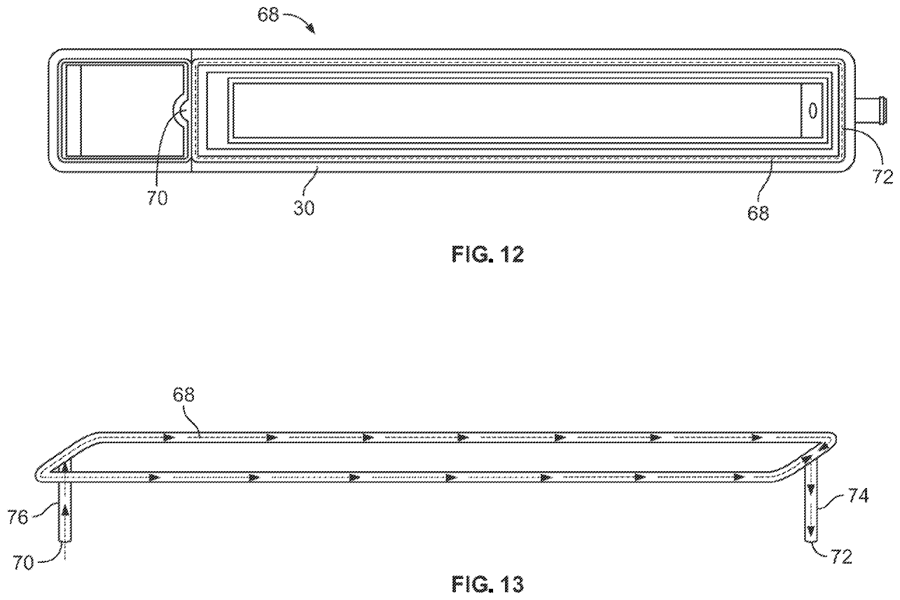

In exemplary aspects, and as shown in FIGS. 12 and 13, the imaging phantom 10 may include a mechanism for infusing the bonding fluid for rapidly bonding the top housing 20 and the bottom housing 30. The bonding fluid, such as epoxy, may be prepared and injected into a first opening 70 in the bottom housing 30. The bonding agent may be travel up a channel 76 in the bottom housing 30 which connects the first opening 70 to the peripheral channel 68. The bonding fluid may travel in two directions to fill or substantially fill the peripheral channel 68. In this example, some of the bonding fluid travels clockwise and some of the bonding fluid travels counterclockwise in the peripheral channel 68. When the peripheral channel 68 is filled or substantially filled, the excess bonding fluid may travel through a channel 74 in the bottom housing 30 which connects the peripheral channel 68 to a second opening 72 in the bottom housing 30. The infusion of the bonding fluid may be completed when the bonding agent begins to travel down the second channel 74 and/or out of the second opening 72. In one aspect, the infusion of the bonding fluid may take approximately 20 seconds. In one aspect, the bonding fluid may set in approximately 5 minutes after completion of the infusion process. Further, the imaging phantom 10 may be used after the bonding fluid is set. This process and mechanism for infusing the bonding fluid may reduce the assembly time of the imaging phantom 10.

### EXAMPLE

A disposable point-of-care portable perfusion phantom for use in multi-institutional settings for quantitative dynamic contrast-enhanced magnetic resonance imaging (qDCE-MRI) was produced as disclosed herein.

The phantom was designed for single-use and imaged concurrently with a human subject so that the phantom data can be utilized as the reference to detect errors in qDCE-MRI measurement of human tissues. The change of contrast-agent concentration in the phantom was measured using liquid chromatography-mass spectrometry. The repeatability of the contrast enhancement curve (CEC) was assessed with five phantoms in a single MRI scanner. Five healthy human subjects were recruited to evaluate the reproducibility of qDCE-MRI measurements. Each subject was imaged concurrently with the phantom at two institutes using three 3T MRI scanners from three different vendors. Pharmacokinetic (PK) parameters in the regions of liver, spleen, pancreas, and paravertebral muscle were calculated based on the Tofts model (TM), extended Tofts model (ETM), and shutter speed model (SSM). The reproducibility of each PK parameter over three measurements was evaluated with the intraclass correlation coefficient (ICC) and compared before and after phantom-based error correction.

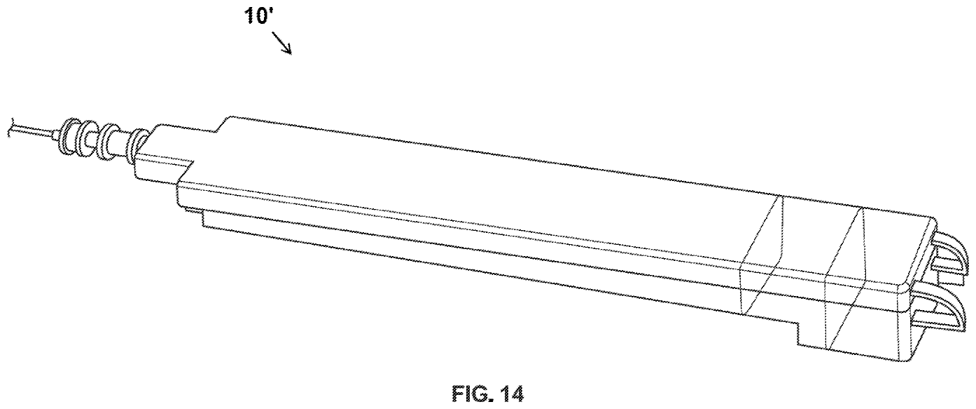

FIG. 14 shows the disposable point-of-care portable perfusion phantom 10′. The phantom has a top housing, a bottom housing, and a semi-permeable membrane as disclosed herein. The semi-permeable membrane (pore size: 12-14 kD, Spectra/Por® 2 dialysis membrane; SpectrumLabs, Rancho Dominguez), was held taut by a plastic frame.

The top half (e.g., the top housing disclosed herein) houses the top chamber (e.g., the first chamber disclosed herein) (height×width×length: 1×15×150 mm³), and the bottom half (e.g., the bottom housing disclosed herein) houses the bottom chamber (e.g., the second chamber disclosed herein) (height×width×length: 15×15×150 mm³). Once the three parts were assembled, the top and bottom chambers were filled with degassed and deionized water. Epoxy was then poured into a channel along the frame to secure the phantom. The phantom demonstrated shelf stability, with no bubbles forming internally for over 6 months. The inlet and outlet were closed with caps for convenient delivery. Before use, the caps were removed, and a polyethylene tube filled with an MR contrast agent was connected to the inlet port. During DCE-MRI, the contrast agent was infused, displacing the water in the top chamber, and it began to diffuse through the membrane to the bottom chamber. The water in the top chamber was transferred to the waste chamber. The phantom was designed using Solid-Works (Dassault Systemes American Corp., Waltham, MA). The phantom was 3D printed on Stratasys Fortus 250 (Stratasys, Eden Prairie, MN) utilizing a fused deposition modeling process with VeroClear material. However, each part of the phantom was compatible with injection molding, which may provide a scalable means of manufacture, low piece-part cost, and a high degree of dimensional accuracy.

A computer fluid dynamics (CFD) simulation was performed on a simplified top chamber geometry using ANSYS Fluent 12.0 (Ansys, Inc., Canonsburg, PA). A laminar, pressure-based, transient, multi-phase solver was used. For validating the CFD analysis accuracy, 12 samples were collected from the phantom outlet at a set interval during the injection of 100 mM of gadoteridol (Bracco Diagnostics, Monroe Township, NJ) into the inlet at a constant rate (0.06 ml/s). The experiment was repeated three times, obtaining a total of 36 samples. The concentration of gadoteridol in the samples was measured using liquid chromatography-mass spectrometry (LC-MS) and compared to the data simulated by the CFD. See Jia J, Keiser M, Nassif A, Siegmund W, Oswald S. A LC-MS/MS method to evaluate the hepatic uptake of the liver-specific magnetic resonance imaging contrast agent gadoxetate (Gd-EOBDTPA) in vitro and in humans. J Chromatogr B Analyt Technol Biomed Life Sci. 2012; 891-892:20-26. The similarity between the LC-MS and CFD data was 0.965 when assessed by the intraclass correlation coefficient. Then, the CFD simulations were performed to optimize the geometric configuration of the top chamber, the infusion rate, and the injection volume of gadoteridol for water displacement. The parameters for optimization were the inlet diameter, the outlet diameter, and the transition shape between the top chamber and inlet/outlet. In the final optimized top chamber, more than 99% of gadoteridol concentration was reached with 4 ml injected at a rate of 0.24 ml/s.

The change of the CAC in the phantom was measured using LC-MS. Two 1-mm holes were drilled on the side of the bottom chamber of a phantom (one at the middle and the other one at the end). A total of 10 samples (0.25 ml) were collected from the middle hole at 1-min intervals after initiating gadoteridol injection (100 mM,4 ml) at a constant rate (0.24 ml/s) using a programmable syringe pump (NE-1000), while the same amount of deionized water was added through the second hole. This process was repeated 10 times, obtaining a total of 100 samples. The gadoteridol concentration in the samples was measured using LC-MS, and then the dilution of the gadoteridol concentration due to the added water volume was accounted for during calculation. The mean and standard deviation (SD) of the gadoteridol concentration at each timestamp was calculated, and the best-fitting regression line was computed and used as the reference contrast enhancement curve (CEC) in this study. The reference CEC measurement accuracy was assessed by one minus the coefficient of variation (SD/mean) averaged over 10 timestamps.

The CEC repeatability of the phantom was measured with five phantoms in a SIEMENS 3T Prisma scanner (Siemens Medical Solutions USA, Inc., Malvern, PA). The phantoms were placed on the scanner table, and a torso phased array coil was placed around them. B₀ and B₁ shimming were initially conducted, and B₁ mapping was followed using vendor software for B₁ inhomogeneity correction. See Chung S, Kim D, Breton E, Axel L. Rapid B1+ mapping using a preconditioning RF pulse with TurboFLASH readout. Magn Reson Med. 2010; 64(2):439-446. T₁-weighted (T1W) imaging was implemented at 2°, 5°, and 10° flip angles to acquire the data necessary to compute a Ti map, followed by DCE-MRI. A 3D fast spoiled gradient echo sequence (VIBE) was employed for both the multi-flip angle T1W imaging and DCE-MRI with the following parameters: frequency/phase encoding=192/156, matrix size=384×312, FOV=400×320 mm, slice number=10, thickness/gap=5/0 mm, flip angle=15°, TR/TE=4.9/2.5 ms, SENSE factor=2, NEX=1, and temporal resolution=2.3 s. See Liberman G, Louzoun Y, Ben Bashat D. T(1) mapping using variable flip angle SPGR data with flip angle correction. J Magn Reson Imaging. 2014; 40(1):171-180. Gadoteridol (100 mM, 4 ml) was infused into all five phantoms simultaneously at 15 s after starting DCE-MRI at a constant rate (0.24 ml/s) using a programmable syringe pump (NE-1600). DCE-MRI continued for 6 min. The entire region of the bottom chamber was automatically segmented using Otsu's thresholding method, and the change of gadoteridol concentration averaged in the region was calculated using a lab-made software package based on LabVIEW v17.0 (NI, Austin, TX). See Xue J H, Titterington D M. t-Tests, F-tests and Otsu's methods for image thresholding. IEEE Trans Image Process. 2011; 20(8):2392-2396. The CECs of five phantoms were retrieved, and the repeatability was assessed with the ICC.

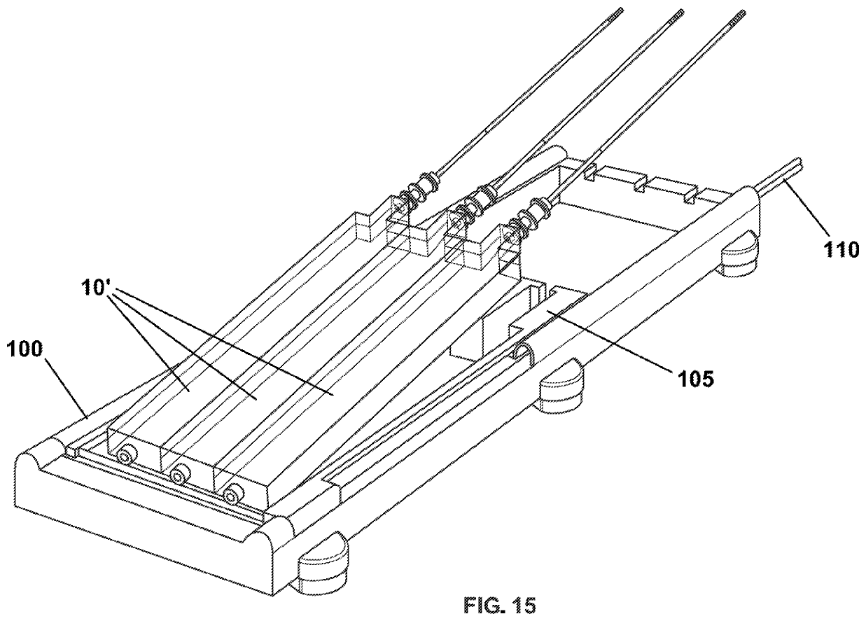

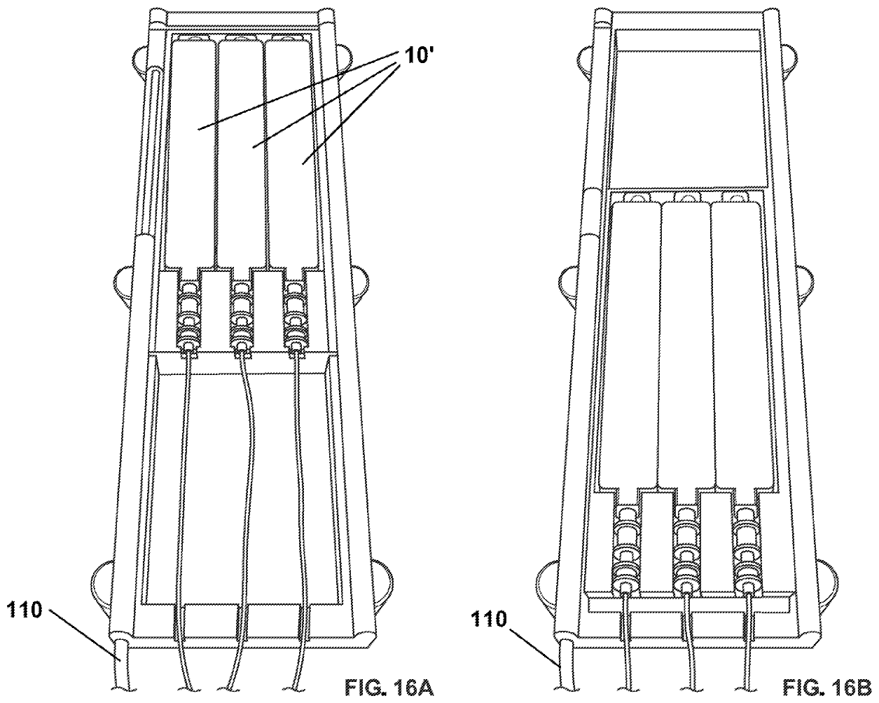

FIG. 15 shows a 3D rendering of the phantom cassette 100, which may house up to three or more phantoms 10′. Multiple phantoms increase the CEC measurement accuracy and also provide redundancy should any one of the phantoms fail. Sorbothane discs (diameter: 2.54 cm) (Sorbothane, Inc., Kent, OH) were placed on the bottom of the cassette to dampen vibrations coming through the scanner table. The pliability of the Sorbothane pads also allows the phantom to be firmly placed on both flat and curved MRI patient tables. Extenders can be added to the bottom of the cassette to raise it closer to the patient when necessary. Two bubble levels were used to ensure the cassette is level in a curved MRI table configuration. As shown in FIG. 15, the cassette 100 can include an interior region that is defined within an outer frame. The phantom(s) 10′ can be received within a support structure 105 (e.g., cradle or receptacle) that is positioned within the interior region of the cassette 100. As shown in FIGS. 16A and 16B, a cable controller 115 is placed at the end of a tabletop insert (discussed further below) to enable independent adjustments of phantom position longitudinally by up to 15 cm without interfering with patient positioning. In exemplary aspects, a cable or rod 110 can be coupled to the support structure 105 within which the phantom(s) are received, and the support structure 105 can be slidingly coupled (or otherwise movably coupled) to the cassette 100. In these aspects, movement of the cable or rod can effect axial translation of the support structure (and phantom(s)) relative to the cassette 100 (and the tabletop insert). Thus, selective axial translation of the cable or rod 110 can effect a corresponding movement of the phantom(s) 10′. To accommodate translation of the phantom(s) 10′, the support structure 105 and/or the outer frame of the cassette 100 can include respective recesses or slots that receive the tubes or conduits that are in fluid communication with the phantom(s). Optionally, the outer frame of the cassette 100 can define a bore that receives the cable 110, and the cable can be coupled or secured to the support structure 105. Optionally, the support structure 105 can comprise an outer portion that slidingly engages a portion of the cassette (e.g., a rail or recess) such that the support structure 105 can slide relative to the cassette 100, thereby permitting adjustment of the position of the phantom(s).

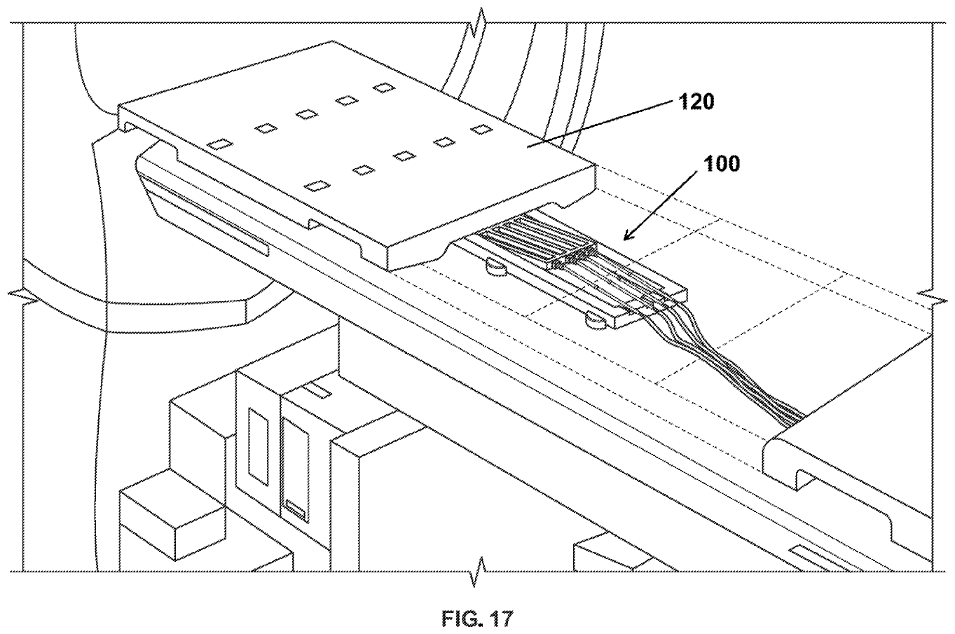

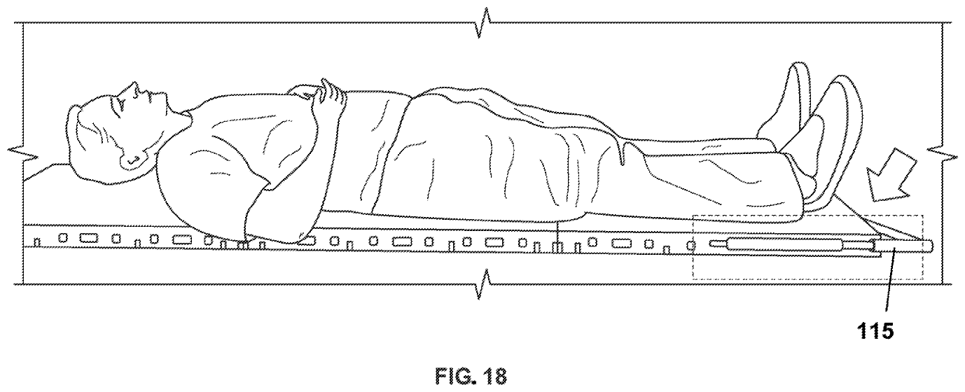

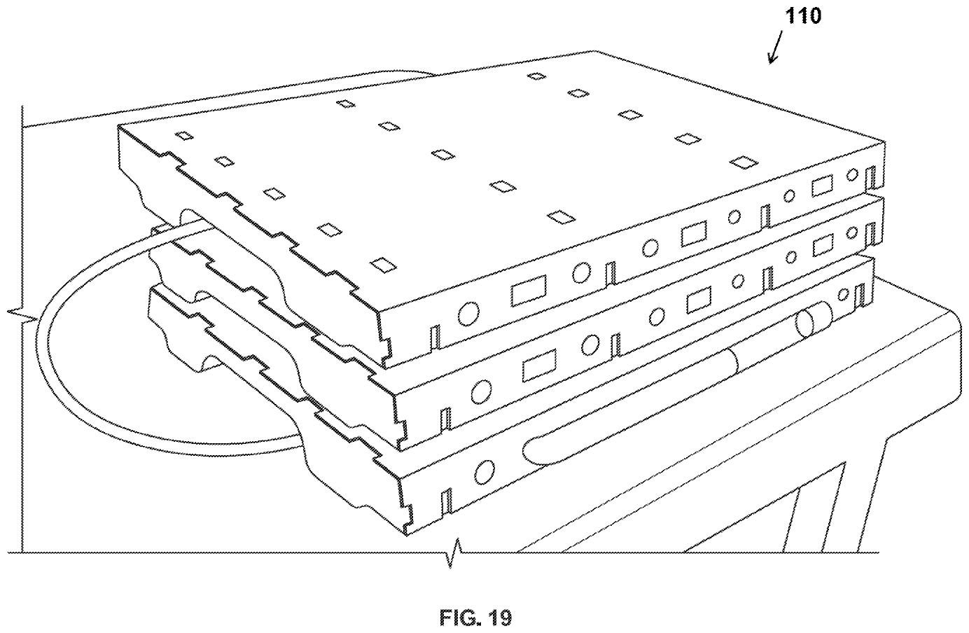

FIG. 17 shows a 3D illustration of a new tabletop insert 120 optimized for the phantom use. The insert (height×width×length=6×48×206 cm, weight=6 kg) was made of wood plates. The surface of the plates was varnished for convenient cleaning with a disinfectant used in an MRI facility. The bottom of the insert is arch-shaped so that the phantoms can be placed under it. This insert has many holes to ventilate the air around the phantoms, dissipating any heat transferred from the human subject. The tabletop insert was designed to be placed on either a flat or curved table. FIG. 18 shows a human subject (height: 180 cm, weight: 85 kg) lying on the insert. Finite element analysis was carried out with ANSYS Fluent 12.0 (Ansys, Inc.) to configure the structure supporting up to 136 kg of body weight when a human subject sits on the insert. Although this weight limit can satisfy most clinical needs, the tabletop insert can be further strengthened to increase weight limits if needed. A cable controller 115 (indicated with an arrow in FIG. 18) is placed at the end of the insert and configured to engage the cable 110, such that manipulation of the cable controller 115 can adjust the phantom location. For example, it is contemplated that the cable controller 115 can comprise a slide bar that engages the cable 110 and is movably (e.g., slidingly) coupled to the tabletop insert 120. In use, the slide bar can slide relative to the tabletop insert 120 and effect a corresponding movement of the cable (and, thus, the phantom(s)). FIG. 19 shows that the tabletop insert 120 can be separated into three panels for convenient carrying and storage.

Five healthy human volunteers without safety contradictions to MRI examination or gadolinium-based MRI contrast agents were recruited. All participants were female, and their ages ranged from 23 to 41 (median: 26 years old). The bodyweight of the volunteers ranged from 59 to 81 kg (median: 68 kg). Three of the volunteers were Caucasian, and two were African American. Each volunteer was imaged together with the phantom package in two 3T MR scanners, GE Signa (GE Healthcare, Chicago, IL) and SIEMENS Prisma (Siemens Medical Solutions USA, Inc.) at UAB, and then traveled to VUMC for the third imaging in another 3T MRI scanner, Philips Elition (Philips Healthcare, Amsterdam, Netherlands). All three MRI scans were completed within a week, assuming that the perfusion parameters of human tissues would minimally change over a week.

All participants were asked to refrain from drinking caffeinated or alcoholic beverages for at least 24 hours before imaging as those may change tissue perfusion. See Daniels J W, Mole P A, Shaffrath J D, Stebbins C L. Effects of caffeine on blood pressure, heart rate, and forearm blood flow during dynamic leg exercise. J Appl Physiol (1985). 1998; 85(1):154-159; Orrego H, Carmichael F J, Israel Y. New insights on the mechanism of the alcohol-induced increase in portal blood flow. Can J Physiol Pharmacol. 1988; 66(1):1-9. The participants were also asked not to eat any solid food for at least 4 h before imaging to minimize the motion artifact induced by peristaltic movement. All three scans were implemented during the daytime to minimize the variation of tissue perfusion by circadian rhythm. See Douma L G, Gumz M L. Circadian clock-mediated regulation of blood pressure. Free Radic Biol Med. 2018; 119:108-114. Three phantoms were inserted into the cassette, as shown in FIG. 15 and placed under the tabletop insert as shown in FIG. 17. Each subject lay on the insert, as shown in FIG. 18, and a torso phased array coil was placed around the abdomen. Before imaging, B₀ and B₁ shimming were conducted, and B₁ mapping was followed using vendor software. See Chung S, Kim D, Breton E, Axel L. Rapid B1+ mapping using a preconditioning RF pulse with TurboFLASH readout. Magn Reson Med. 2010; 64(2):439-446; Sacolick L I, Wiesinger F, Hancu I, Vogel M W. Bl mapping by Bloch-Siegert shift. Magn Reson Med. 2010; 63(5):1315-1322; Nehrke K, Bornert P. DREAM-a novel approach for robust, ultrafast, multislice B(1) mapping. Magn Reson Med. 2012; 68(5):1517-1526. The coefficient of variation of B₁ value over the human body region was in the range of 11-21% (mean±SD: 13±3%), while that in the phantom region was in the range of 1-4% (mean±SD: 2±1%).

For T₁ mapping, T1W imaging was implemented at various flip angles (2°, 5°, and 10°) using a 3D fast spoiled gradient echo sequence (VIBE and FSPGR in the SIEMENS and GE scanners, respectively) or a 3D spoiled gradient-echo sequence (T1-FFE in the Philips scanner). See Liberman G, Louzoun Y, Ben Bashat D. T(1) mapping using variable flip angle SPGR data with flip angle correction. J Magn Reson Imaging. 2014; 40(1):171-180. Imaging parameters in the SIEMENS scanner were identical to those used for phantom repeatability measurement. In the GE scanner, the imaging parameters were as follows: frequency/phase encoding=192/173, matrix size=256×230, FOV=400×360 mm, slice number=12, thickness/gap=5/0 mm, TR/TE=3.8/2.1 ms, SENSE factor=2, NEX=1, and temporal resolution=2.9 s. In the Philips scanner, the imaging parameters were as follows: frequency/phase encoding=200/200, matrix size=256×256, FOV=400×400 mm, slice number=12, thickness/gap=5/0 mm, TR/TE=20/4.6 ms, SENSE factor=2, NEX=1, and temporal resolution=9.7 s. T1W imaging was continued for 30 s in a free-breathing mode in the SIEMENS and GE scanners, and the images acquired at the expiration phase were automatically selected and averaged. For the Philips scanner, T1W images were acquired at end-expiration breath-hold due to the slower temporal resolution.

In the GE and SIEMENS scanners, DCE-MRI imaging sequences and parameters were identical to those used for T₁ mapping, except for the fixed flip angle (15° and 20° in SIEMENS and GE scanners, respectively). In the Philips scanner, DCE-MRI was conducted using a 3D fast spoiled gradient sequence (THRIVE) with the same imaging parameters as those in the T1W imaging, except the fixed flip angle at 20° and TR/TE=5/2.3 ms (temporal resolution=3.0 s). DCE-MRI continued for 9 min in a free-breathing mode. Gadoteridol (0.1 mmol/kg) was intravenously injected at 2 ml/s starting at 30 s after initiation of DCE-MRI and flushed with 20 ml of saline (2 ml/s) using the clinical power injector at each site. Gadoteridol (100 mM) was injected into three phantoms at 15 s after starting DCE-MRI (0.24 ml/s, 4 ml) using a syringe pump (NE-1600). For this manuscript, the SIEMENS, GE, and Philips scanners were labeled Scanner 1, Scanner 2, and Scanner 3, respectively.

DCE-MRI images were processed to retrieve PK maps as follows. First, the motion of each human subject was automatically tracked, and the images acquired at the expiration phase were selected. Li Z, Tielbeek J A, Caan M W, et al. Expiration-phase template-based motion correction of free-breathing abdominal dynamic contrast enhanced MRI. IEEE Trans Biomed Eng. 2015; 62(4):1215-1225. Second, a Ty map was created using the multi-flip angle method, while the flip-angle variation was corrected using the BI map. Kim H, Samuel S, Totenhagen J W, Warren M, Sellers J C, Buchsbaum D J. Dynamic contrast enhanced magnetic resonance imaging of an orthotopic pancreatic cancer mouse model. J Vis Exp. 2015. Third, a look-up table (LUT) was created using the phantom, correlating the reference CEC obtained by the LC-MS with the measured one by DCE-MRI (the detailed procedure of LUT creation is in Appendix B of a previous paper). See Kim H, Mousa M, Schexnailder P, et al. Portable perfusion phantom for quantitative DCE-MRI of the abdomen. Med Phys. 2017; 44(10):5198-5209. Fourth, the CAC map was created using Bokacheva et al.'s method, while the flip-angle variation was corrected using the By map, and the errors in quantitating CAC were corrected using the LUT equation. Bokacheva L, Rusinek H, Chen Q, et al. Quantitative determination of Gd-DTPA concentration in T1-weighted MR renography studies. Magn Reson Med. 2007; 57:1012-1018. The LUT equation defines the correlation between the CACs with and without errors. Thus, using the LUT equation, the CAC in a tissue with errors can be converted to the CAC without errors (the detailed procedure of error correction in the CAC using the LUT equation is also described in Appendix B of a previous paper). See Kim H, Mousa M, Schexnailder P, et al. Portable perfusion phantom for quantitative DCE-MRI of the abdomen. Med Phys. 2017; 44(10):5198-5209. Fifth, the PK maps were created based on the Tofts model (TM), extended Tofts model (ETM), and shutter speed model (SSM). See Tofts PS. Modeling tracer kinetics in dynamic Gd-DTPA MR imaging. J Magn Reson Imaging. 1997; 7(1):91-101; Tofts P S, Brix G, Buckley D L, et al. Estimating kinetic parameters from dynamic contrast-enhanced T(1)-weighted MRI of a diffusable tracer: standardized quantities and symbols. J Magn Reson Imaging. 1999; 10(3):223-232; Li X, Huang W, Yankeelov T E, Tudorica A, Rooney W D. Shutterspeed analysis of contrast reagent bolus-tracking data: preliminary observations in benign and malignant breast disease. Magn Reson Med. 2005; 53(3):724-729.In this study, a population-based arterial input function (AIF) was used, and the hematocrit was assumed to be 0.45 for all subjects when calculating the plasma input function (PIF=AIF/(1−hematocrit)). See Parker G J, Roberts C, Macdonald A, et al. Experimentally derived functional form for a population-averaged high-temporal resolution arterial input function for dynamic contrast-enhanced MRI. Magn Reson Med. 2006; 56(5):993-1000. A total of 11 PK maps (TM: K^{trans}, kₑₚ, and νₑ; ETM: K^{trans}, kₑₚ, νₑ, and τₚ; SSM: K^{trans}, kₑₚ, νₑ, and τᵢ) were constructed per imaging session per subject. See Kim H. Variability in quantitative DCE-MRI: sources and solutions. J Nat Sci. 2018; 4(1):e484. K^{trans} (unit: min⁻¹) is the blood efflux rate from the vessel to the extravascular and extracellular space, k^{ep} (unit: min⁻¹) is the blood influx rate from the extravascular and extracellular space to the vessel, νₑ is the fractional extravascular and extracellular space, νₚ is the fractional plasma volume, and the τᵢ (unit: second) is the mean intracellular water lifetime.

A single slice, including the liver, pancreas, spleen, and prevertebral muscle, was selected, and the PK parameter values within the entire tissue region were averaged. The tissue regions were manually segmented from the DCE-MRI images coregistered at the expiration phase and acquired at the late arterial phase (40-45 s postcontrast agent injection) using an image processing software, ImageJ (National Institutes of Health, Bethesda, MD). The reproducibility of each PK parameter over three scanners was assessed with the ICC. Image processing was conducted using a lab-made computer software package based on Lab-VIEW v17.0, while the subfunction for SSM-based PK mapping was programmed using MATLAB v2020a (Mathworks, Natick, MA). T1 mapping and TM/ETMbased PK mapping were validated using the digital reference objects (DROs) generated by Dr. Barboriak's group (Duke University) and the Quantitative Imaging Biomarker Alliance (QIBA), while the DRO validating SSM-based PK mapping was created in this study. See Barboriak DP QIBA—Digital Reference Object for Profile DCE-MRI Analysis Software Verification 2. https://scholars.duke./u/display/gra211722 (last date of access: Jul. 19, 2018). The ICC between the reference values of DROs and the calculated PK parameters was higher than 0.98 regardless of the PK model.

The CEC repeatability of the phantom and the reproducibility of each PK parameter of human tissues were assessed by the ICC. See Koo T K, Li M Y. A guideline of selecting and reporting intraclass correlation coefficients for reliability research. J Chiropr Med. 2016; 15(2):155-163. Two data points of a single subject were outliers in the regression line of ETM-based K^{trans} (the residuals of the data points from the regression line were higher than two SDs of the residuals of all data points) and were thus excluded. The within-subject coefficient of variation (wCV) was estimated to determine the reproducibility of the PK parameter calculation for each tissue. The wCVs of each PK parameter before and after phantom-based error correction were compared using one-way ANOVA. See Neter J, Kutner MH, Nachtsheim JC, Wasserman W. Applied Linear Statistical Models. 4th ed. McGraw-Hill Companies, Inc.; 1996. All data are represented by mean±SD, and p value less than 0.05 was considered significant. All statistical analyses were conducted using SAS v9.4 (SAS Institute Inc., Cary, NC).

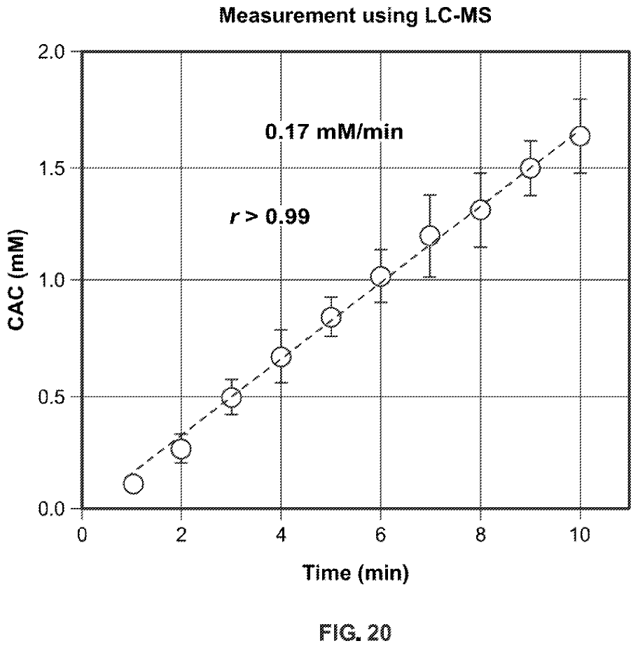

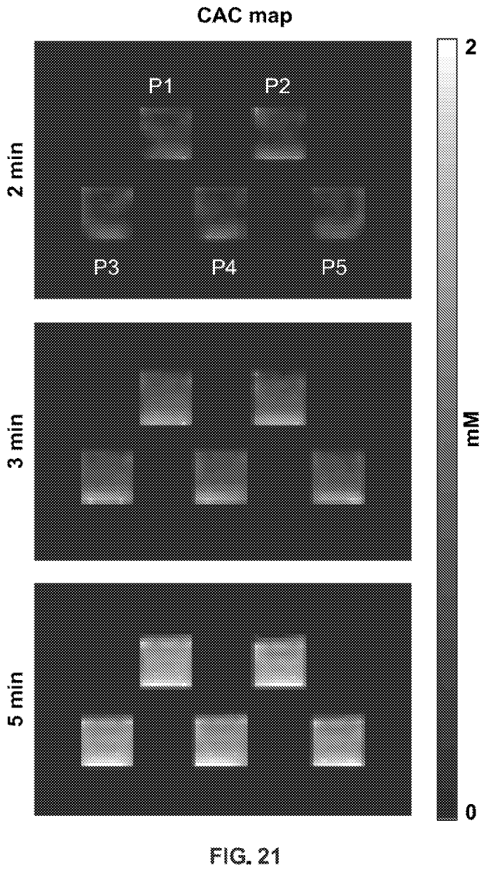

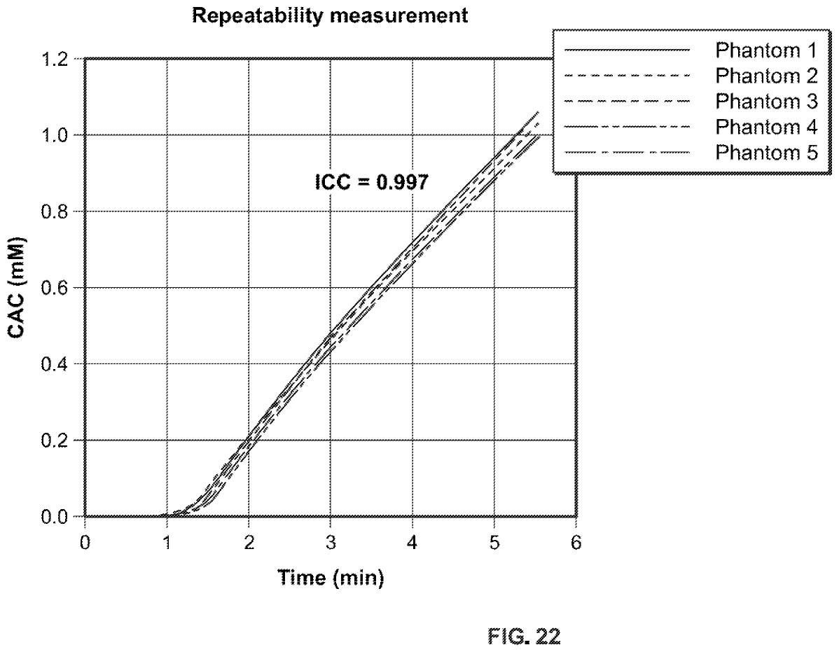

The contrast concentration in the phantom was linearly increased for 10 min (0.17 mM per minute) after gadoteridol injection with 96% measurement accuracy. FIG. 20 shows the change of CAC averaged in the bottom chamber of the phantom after starting the injection of gadoteridol (100 mM) at a constant rate (0.24 ml/s, 4 ml). The correlation coefficient, r, of the regression line was 0.996. FIG. 21 shows the CAC maps in the bottom chambers of the five phantoms (P1-P5) at 2, 3, and 5 min after starting DCE-MRI when the gadoteridol (100 mM) was infused at 15 s after starting DCE-MRI (0.24 ml/s, 4 ml). FIG. 22 shows the CECs of the five phantoms. The repeatability of the CEC was 0.997 when assessed by the ICC. The coefficient of variation (COV) of the measured CECs across three scanning sessions of five volunteers was 50% when calculated by averaging 10 COVs obtained at every minute for 10 min.

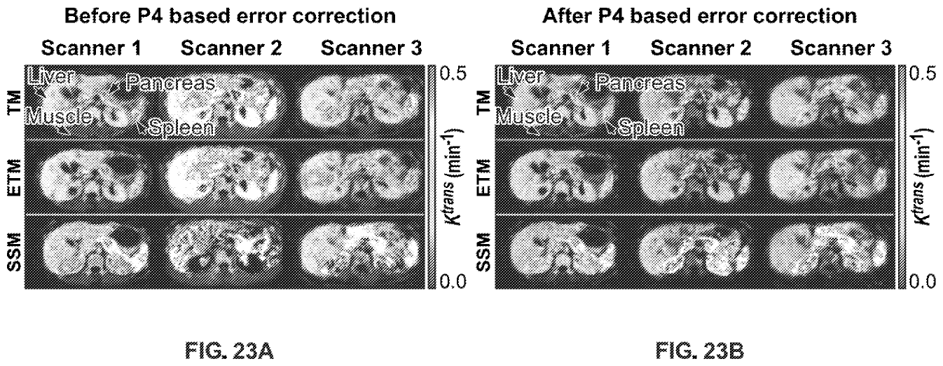

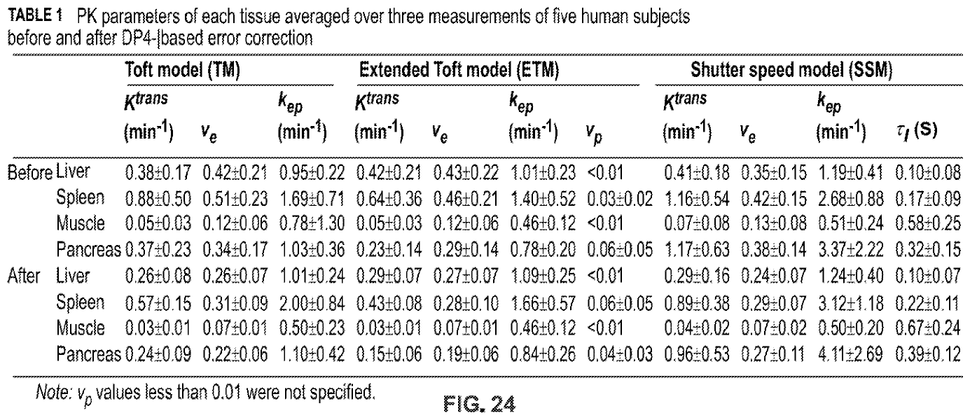

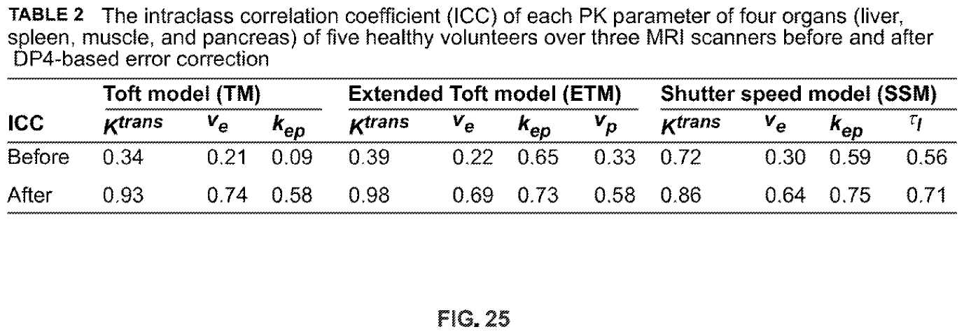

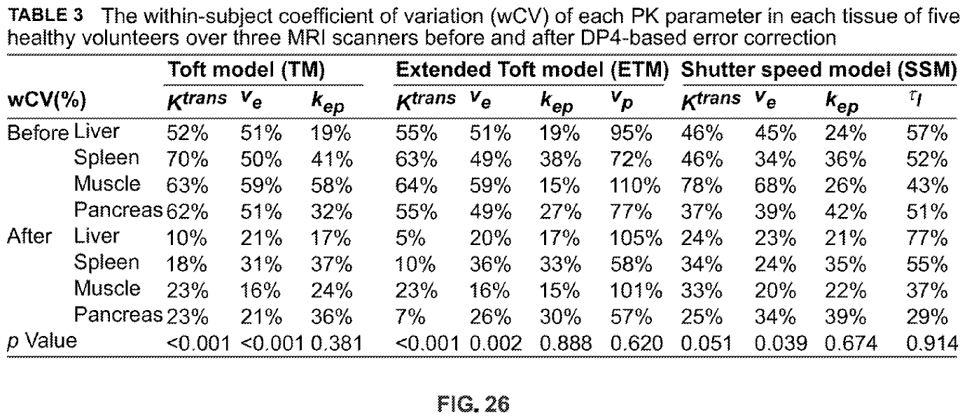

FIGS. 23A and 23B show the K^{trans} maps of a healthy volunteer obtained from three 3T MRI scanners when the TM, ETM, and SSM were employed before and after phantom-based error correction. The regions of the spleen, liver, pancreas, and paravertebral muscle are indicated with red arrows. Table 1 shown in FIG. 24 shows the PK parameters of each tissue averaged over three measurements of five human subjects (three measurements x five subjects), and Table 2 shown in FIG. 25 shows the reproducibility of each PK parameter calculation across all three scanners (four tissues×five subjects), before and after phantom-based error correction. The reproducibility (ICC) was increased up to sixfold after phantom-based error correction. The ICC of K^{trans} was highest after error correction, regardless of the PK models. Table 3 shows the wCV of each PK parameter in each tissue across three MRI scanners. The wCV of the PK parameter was reduced up to 10-fold after phantom-based error correction. The wCVs of K^{trans} and νₑ were significantly reduced in TM and ETM after error correction, but those of kₑₚ and νₚ were not. In SSM, the wCVs of K^{trans} and νₑ were markedly reduced but not statistically significant.

It was demonstrated that the reproducibility of PK parameter of human tissues was significantly improved when the phantom-based error correction method was used in qDCE-MRI. The errors in the T1 calculation and PK modeling can be detected and corrected using DROs. Thus, the errors in PK parameter quantification fundamentally stem from the miscalculation of CAC. An SPGR sequence, T1-FFE, was used for multi-flip angle T₁ mapping in our study. Regular SPGR sequences yield a relatively slower temporal resolution and are suboptimal for DCE-MRI, particularly for the abdomen. Ideally, a unique equation may be driven for each sequence. However, developing equations for all the sequences would be challenging. Therefore, the point-of-care phantom-based error correction strategy is a reasonable alternative to improve the reproducibility of qDCE-MRI measurement. The high reproducibility of qDCE-MRI measurement may allow the direct comparison of tissue perfusion data across clinical sites for accurate quantitation, diagnosis, and prognosis.

The diffusion of a contrast agent via the semi-permeable membrane is mainly driven by osmotic pressure, so the added water during sampling for CEC measurement may change the diffusion rate. However, the amount of water added at each minute is only 0.7% of the total water in the bottom chamber. So, although the diffusion rate was 0.7% increased at each minute, the CEC would still be linear (r>0.99) with a slope of 0.174 mM/min, which is only 2% larger than our estimation (0.17 mM/min).

The K^{trans} in the ETM presented the highest reproducibility after phantom-based error correction, consistent with a previous study. See Kim H, Mousa M, Schexnailder P, et al. Portable perfusion phantom for quantitative DCE-MRI of the abdomen. Med Phys. 2017; 44(10):5198-5209. The K^{trans} is the measurement of the wash-in rate. Therefore, if the wash-in occurs rapidly, the K^{trans} may be more insensitive to noise and motion artifacts; this may explain the high reproducibility of K^{trans} in the highly perfused tissues like the liver, pancreas, and spleen, not in the muscle. The low reproducibility of νₚ was primarily caused by its low signal-to-noise ratio.

A population-based AIF was employed when retrieving PK parameters because severe motion artifacts in the abdominal aorta region were observed in a few DCE-MRI scans. In Parker et al.'s study, the COV of the population-based AIF obtained from 23 cancer patients (total 67 DCE-MRI sessions with a single 1.5T scanner) was about 30%. A 30% variation in the AIF may lead to about 30% variation in both K^{trans} and νₑ. See Parker G J, Roberts C, Macdonald A, et al. Experimentally derived functional form for a population-averaged high-temporal resolution arterial input function for dynamic contrast-enhanced MRI. Magn Reson Med. 2006; 56(5):993-1000. However, the AIF variation of the same subject after a previously designed phantom-based correction may be much lower. The variation of the individual AIF is mainly caused by the variation in the total blood volume and cardiac output. The total blood volume of a subject may be minimally changed during a week. However, the cardiac output may vary during a DCE-MRI scan, which may not be compensated with a population-based AIF. The relatively lower reproducibility of νₑ or kₑₚ was caused by a single subject's data on an MRI examination. Excluding the subject's data, the reproducibility (measured by ICC) of ETM νₑ or kₑₚ is improved to 0.91 and 0.88, respectively. It was presumed that the subject's cardiac output was increased after starting DCE-MRI on that day, leading to the higher νₑ and kₑₚ. Also, the phantom-based error correction tends to decrease the SD for K^{trans} and νₑ, but not kₑₚ, particularly in the TM/ETM. When a population-based AIF is employed, the error in estimating the CAC in a tissue may affect K^{trans} and νₑ, not kₑₚ in the TM/ETM as long as the error is linear.

The total duration of DCE-MRI may determine the dynamic range of the disposable point-of-care portable perfusion phantom. For example, if DCE-MRI continues for 5 min after contrast enhancement in the phantom, the dynamic range of the disposable point-of-care portable perfusion phantom may be 0.85 mM (0.17 mM/min×5 min), covering the dynamic ranges of most tissues except the AIF. However, if a novel method to estimate the individual AIF by modifying the population-based AIF with the individual variation of the cardiac output and the blood volume is employed, the scanner-dependent error in the AIF can be corrected using the dynamic range of the disposable point-of-care portable perfusion phantom (see “Appendix A” of a previous paper for details). See Neter J, Kutner M H, Nachtsheim J C, Wasserman W. Applied Linear Statistical Models. 4th ed. McGraw-Hill Companies, Inc.; 1996; Kim H, Mousa M, Schexnailder P, et al. Portable perfusion phantom for quantitative DCE-MRI of the abdomen. Med Phys. 2017; 44(10):5198-5209. However, the disposable point-of-care portable perfusion phantom cannot be used to correct the other concerns in the AIF, such as the pulsated inflow effect and the partial volume effect. A median filtering or the modified population-based AIF42 can be used to reduce the pulsated inflow effect. The segmented aorta region may need to be downsized by 2 mm as proposed in our previous study to reduce the partial volume effect. Kim H, Morgan D H. Semiautomatic determination of arterial input function in DCE-MRI of the abdomen. J Biomed Eng Med Imaging. 2017; 4(2):96-104.

The SSM-based K^{trans} of the pancreas was four-to-six-fold larger than that in the TM or ETM. Both the TM and ETM assume that the exchange of water molecules between cells and extracellular space is infinitely fast, whereas the SSM does not. Li X, Huang W, Yankeelov T E, Tudorica A, Rooney W D. Shutterspeed analysis of contrast reagent bolus-tracking data: preliminary observations in benign and malignant breast disease. Magn Reson Med. 2005; 53(3):724-729. Therefore, the K^{trans} in the SSM is generally larger than that in the TM or ETM. Huang W, Li X, Morris E A, et al. The magnetic resonance shutter speed discriminates vascular properties of malignant and benign breast tumors in vivo. Proc Natl Acad Sci USA. 2008; 105(46):17943-17948; Li X, Huang W, Morris E A, et al. Dynamic NMR effects in breast cancer dynamic-contrast-enhanced MRI. Proc Natl Acad Sci USA. 2008; 105(46):17937-17942; Tudorica L A, Oh K Y, Roy N, et al. A feasible high spatiotemporal resolution breast DCE-MRI protocol for clinical settings. Magn Reson Imaging. 2012; 30(9):1257-1267; Huang W, Tudorica L A, Li X, et al. Discrimination of benign and malignant breast lesions by using shutter-speed dynamic contrast-enhanced MR imaging. Radiology. 2011; 261(2):394-403; Li X, Priest R A, Woodward W J, et al. Feasibility of shutter-speed DCE-MRI for improved prostate cancer detection. Magn Reson Med. 2013; 69(1):171-178. The mean intracellular water lifetime, τᵢ, in the pancreas was about four-fold higher than that in the liver, explaining the high K^{trans} in the pancreas when the SSM is employed. Pancreatic adenocarcinoma is typically hypoperfused; thus, the SSM-based K^{trans} map may yield higher contrast between the tumor and normal pancreatic parenchyma, leading to improved diagnostic accuracy and/or therapy assessment. A subsequent clinical study may need to be conducted to test this hypothesis.

To date, static phantoms have been commonly utilized to evaluate the reproducibility of qDCE-MRI measurement over multiple sites due to cost-effectiveness and ease of use. However, a live tissue has microvessels, where the contrast agents travel through. The movement of contrast agents may reduce the MRI signal additionally, which a static phantom cannot replicate. Therefore, it is uncertain whether static phantoms are valid for quality assurance of qDCE-MRI measurement in patients. In this study, human subjects were employed to evaluate the reproducibility of qDCE-MRI measurement with and without phantom-based error correction. It was assumed that intrasubject variation would be minimal within 1 week, but two data points (liver and spleen) of a single subject were categorized as outliers in this study. This phenomenon cannot be explained but it is presumed that the subject might have had caffeinated drinks unknowingly before one of the scanning sessions, which could affect the observed perfusion parameters. Each volunteer's experience was purposefully limited to three sessions. The repeated injection of gadolinium-based MRI contrast agents may induce adverse events for healthy volunteers, risks that are currently unknown. Gulani V, Calamante F, Shellock F G, Kanal E, Reeder S B; International Society for Magnetic Resonance in Medicine. Gadolinium deposition in the brain: summary of evidence and recommendations. Lancet Neurol. 2017; 16(7):564-570.

In this study, the repeatability of qDCE-MRI measurement was not assessed. The repeatability is typically higher than the reproducibility. If high repeatability can be achieved, the relative change (%) of the PK parameter can be utilized as a surrogate imaging biomarker for therapy monitoring. The repeatability is fundamentally limited by the intrascanner variability. It was previously demonstrated that the magnitude of the intrascanner variability varies across scanners (see Supplementary Material S2 in a previous paper). See Kim H, Thomas J V, Nix J W, Gordetsky J B, Li Y, Rais-Bahrami S. Portable perfusion phantom offers quantitative dynamic contrast-enhanced magnetic resonance imaging for accurate prostate cancer grade stratification: a pilot study. Acad Radiol. 2021; 28(3):405-413. If there is a clinical need for high accuracy in perfusion measurement (e.g., pancreatic cancer therapeutic response assessment), the phantom can be utilized for data quality assurance regardless of the intrascanner variability. Since the phantoms can be imaged together with a patient, reserving extra time for scanner calibration may be unnecessary.

For use in routine clinical practice, the phantom may be portable, affordable, and easily operable. The phantom and auxiliary devices (phantom cassette and wooden tabletop insert) were designed to be conveniently stored and carried. All main parts of the phantom are injection moldable for mass production, so it is expected that the cost of three phantoms may be orders of magnitude less than the cost of the MRI examination. Since the phantom is triggered by a simple infusion of the contrast agent, MRI technologists may be able to operate it after modest training.

There are limitations to the implementation of this methodology for clinical practice. First, the height of the tabletop insert is approximately 6 cm, so the space for the patient inside the bore of the MRI scanner may be reduced by that distance. This may increase the risk of claustrophobia for some patients. Second, installing the phantom and auxiliary equipment on the MRI table takes approximately 5 min, which might have patient throughput effects in a busy clinical MR scanning environment. Third, the tabletop insert might need to be customized (or at least confirmed) for use in various clinical scanners since the MRI table dimensions may vary across scanners.

A disposable point-of-care portable perfusion phantom was developed that can be utilized simultaneously with a human subject during MR scanning. The phantom-based error correction significantly improved the reproducibility of qDCE-MRI measurement and thus may enable the quantitative comparison of perfusion data across clinical settings for improved diagnosis and prognosis, where these quantitative data are employed to assess oncologic, inflammatory, and neurodegenerative diseases. This device can also be utilized to improve the repeatability of qDCE-MRI measurement for therapy monitoring, facilitating the development of novel drugs, particularly antiangiogenic agents. The phantom and the auxiliary devices were optimized for examining the abdomen but could be modified for other anatomical locations, such as the brain and breast.

All publications and patent applications mentioned in the specification are indicative of the level of those skilled in the art to which this invention pertains. All publications and patent applications are herein incorporated by reference to the same extent as if each individual publication or patent application was specifically and individually indicated to be incorporated by reference.

Although the foregoing invention has been described in some detail by way of illustration and example for purposes of clarity of understanding, certain changes and modifications may be practiced within the scope of the appended claims.

What is claimed is:

1. A disposable imaging phantom comprising:
a top housing comprising an inlet, an outlet, and a first chamber in communication with the inlet and the outlet;
a bottom housing comprising a second chamber, the bottom housing configured to connect to the top housing; and
a membrane assembly configured to be positioned between portions of the top housing and portions of the bottom housing,
wherein the first chamber and the second chamber are configured to receive a first fluid and wherein the first chamber is configured to receive a second fluid through the inlet of the top housing to displace the first fluid through the outlet of the top housing,
wherein the membrane assembly comprises a semi-permeable membrane that is configured to permit diffusion of the second fluid from the first chamber into the second chamber.

2. (canceled)

3. (canceled)

4. The imaging phantom of claim 1, wherein a diameter of the outlet of the top housing is larger than a diameter of the inlet of the top housing, wherein a length of the outlet of the top housing is shorter than a length of the inlet of the top housing, wherein the inlet of the top housing, the outlet of the top housing, and the first chamber comprise rounded edges, wherein the inlet and outlet of the top housing are offset from the first chamber along a vertical axis.

5. (canceled)

6. (canceled)

7. (canceled)

8. The imaging phantom of claim 1, further comprising a coupling assembly configured to deliver fluid to the inlet of the top housing, wherein the top housing has a first end portion that comprises the inlet, wherein the first end portion of the top housing further comprises a connector having an inner surface that defines a receiving space, wherein the receiving space is configured to receive a portion of the coupling assembly.

9. (canceled)

10. (canceled)

11. The imaging phantom of claim 108, wherein the connector of the first end portion of the top housing comprises at least one projection extending inwardly from the inner surface of the connector, wherein the coupling assembly comprises a tube having an outer surface, wherein the outer surface of the tube of the coupling assembly defines at least one groove that is complementary to a corresponding projection of the connector of the first end portion of the top housing.

12. The imaging phantom of claim 11, wherein the first end portion of the top housing further comprises a seal that surrounds a portion of the tube of the coupling assembly, and wherein the inner surface of the connector of the first end portion of the top housing defines a notch configured to receive the seal.

13. The imaging phantom of claim 12, wherein the seal is an O-ring.

14. The imaging phantom of claim 11, wherein the coupling assembly further comprises a one-way check valve.

15. The imaging phantom of claim 14, wherein the tube of the coupling assembly is a flexible tube, and wherein the one-way check valve is coupled to the connector of the first end portion of the top housing via the flexible tube.

16. The imaging phantom of claim 14, wherein the one-way check valve is a disc valve.

17. The imaging phantom of claim 15, wherein the coupling assembly further comprises a luer lock fitting that is configured for complementary engagement with a fitting in communication with a fluid source.

18. The imaging phantom of claim 1, wherein the top housing has a second end portion that comprises the outlet, wherein the second end portion of the top housing further comprises:
an opening in fluid communication with the first chamber of the top housing; and
an expandable seal defining a central bore and received within the opening of the second end portion of the top housing, wherein the central bore of the expandable seal is in alignment with the outlet of the top housing.

19. (canceled)

20. The imaging phantom of claim 18, further comprising a seal engagement assembly, wherein the seal engagement assembly comprises a rod configured to be received through the outlet and the central bore of the expandable seal of the second end portion of the top housing, wherein advancement of the rod through the central bore of the expandable seal causes radial expansion of the expandable seal.

21. The imaging phantom of claim 20, wherein the rod of the seal engagement assembly has a first end that is configured to be received within the central bore of the expandable seal of the second end portion of the top housing, wherein the first end of the rod has a variable outer diameter, and wherein the outer diameter decreases towards a tip of the first end of the rod such that further advancement of the rod within the expandable seal causes further engagement between the rod and the expandable seal.

22. The imaging phantom of claim 20, wherein the expandable seal is an O-ring.

23. The imaging phantom of claim 1, wherein:
the top housing has an upwardly facing surface and an opposing downwardly facing surface, wherein the top housing has an outer projection and an inner projection that extend downwardly from the downwardly facing surface of the top housing and define a first channel portion,
the bottom housing comprises a downwardly facing surface and an opposing upwardly facing surface, wherein the bottom housing has an outer projection and an inner projection that extend upwardly from the upwardly facing surface of the bottom housing and define a second channel portion that is in alignment with the first channel portion, wherein the first and second channel portions together define a peripheral channel that extends around the first and second chambers, and
the membrane assembly further comprises a rigid frame to which the semi-permeable membrane is secured,
wherein the peripheral channel is configured to receive the rigid frame, and wherein the semi-permeable membrane is configured to extend across the second chamber between opposing portions of the peripheral channel.

24. The imaging phantom of claim 23, wherein the inner projection of the bottom housing defines a recess, and wherein the inner projection of the top housing comprises a protrusion that is complementary to the recess of the inner projection of the bottom housing, wherein the semi-permeable membrane is configured to be retained between the protrusion of the inner projection of the top housing and the recess of the inner projection of the bottom housing.

25. The imaging phantom of claim 23, wherein the semi-permeable membrane is slack within the rigid frame.

26. The imaging phantom of claim 25, wherein the semi-permeable membrane is taut after the protrusion is inserted into the recess.

27. The imaging phantom of claim 1, wherein:
the top housing includes a first channel portion,
the bottom housing includes a second channel portion in alignment with the first channel portion,
at least one of the top housing and the bottom housing includes a first opening and a third channel that extends from the first opening to at least one of the first channel portion or the second channel portion, and
at least one of the top housing and the bottom housing includes a second opening and a fourth channel that extends from the second opening to at least one of the first channel portion or the second channel portion,
wherein the first and second channel portions together form a peripheral channel that is configured to receive a bonding fluid injected into the first opening, the bonding fluid configured to fill the peripheral channel and exit out the second opening.

28. The imaging phantom of claim 27, wherein the membrane assembly further comprises a rigid frame to which the semi-permeable membrane is secured, and wherein the rigid frame is secured within the peripheral channel by the bonding fluid.
